(19) United States
(12) Patent Application Publication
(10) Pub. No.: US 2014/0045296 A1
(43) Pub. Date: Feb. 13, 2014

(54) High Voltage Opto-Electric Switch

(71) Applicant: COMPACT PARTICLE ACCLERATION CORPORATION, Livermore, CA (US)

(72) Inventors: Cameron Hettler, Livermore, CA (US); Antonios Zografos, Oakland, CA (US); Cecile Cohen-Jonathan, Livermore, CA (US)

(73) Assignee: Compact Particle Accleration Corporation, Livermore, CA (US)

(21) Appl. No.: 13/829,967

(22) Filed: Mar. 14, 2013

Related U.S. Application Data
(60) Provisional application No. 61/680,782, filed on Aug. 8, 2012.

(51) Int. Cl. H01L 31/02

(52) U.S. Cl. CPC H01L 31/02019
USPC 438/98; 438/675

(57) ABSTRACT

Improvements for optically activated electric switches are considered. Techniques are presented for reducing the peaking of the electric field at edge of the contacts. For the body of the opto-switch, methods are described to increase the number of traps. Improvements in illumination are also discussed.

### CROSS-REFERENCE TO RELATED APPLICATION

This application claims priority from U.S. Provisional Application No. 61/680,782, filed on Aug. 8, 2012, which is hereby incorporated in its entirety by this reference.

### BACKGROUND

1. Field of the Invention

This invention relates to high voltage, optically activated electrical switches.

2. Background Information

Optically activated electrical switches can be formed of a semiconductor that, when illuminated by a light source, turns conductive. Contacts are formed on a body, such silicon carbide (SiC), a voltage is applied across the contacts, and the switch is then illuminated. More detail on examples of such switches is described in: G. Caporaso, “New Trends in Induction Accelerator Technology”, Proceeding of the International Workshop on Recent Progress in Induction Linacs, Tsukuba, Japan, 2003; G. Caporaso, et. al., Nucl Instr. and Meth. in Phys. B 261, p. 777 (2007); G. Caporaso, et. al., “High Gradient Induction Accelerator”, PAC '07, Albuquerque, June 2007; G. Caporaso, et. al., “Status of the Dielectric Wall Accelerator”, PAC '09, Vancouver, Canada, May 2009; J. Sullivan and J. Stanley, “6H-SiC Photoconductive Switches Triggered Below Bandgap Wavelengths”, Power Modulator Symposium and 2006 High Voltage Workshop, Washington, D.C. 2006, p. 215 (2006); James S. Sullivan and Joel R. Stanley, “Wide Bandgap Extrinsic Photoconductive Switches” IEEE Transactions on Plasma Science, Vol. 36, no. 5, October 2008; and Gyawali, S. Fessler, C. M. Nunnally, W. C. Islam, N. E., “Comparative Study of Compensated Wide Band Gap Photo Conductive Switch Material for Extrinsic Mode Operations”, Proceedings of the 2008 IEEE International Power Modulators and High Voltage Conference, 27-31 May 2008, pp. 5-8. As these switches can be used in very high voltage applications, the demands placed upon such switches can consequently be quite high and there is consequently an ongoing demand for improvements in such devices.

### SUMMARY OF THE INVENTION

Improvements for various aspects of the sort of switches descried in the Background section are considered. Various ways of forming the contacts on the switch body are considered. Techniques for improving the properties of the switch body, such as increase the trap density, are presented. Alternate ways for illuminating the switch are also considered.

More specifically, a first set of aspects relate to a method of forming a high voltage electrical switch. This includes receiving a semi-conductor switch body and forming a first dielectric layer over a first surface of the switch body. The first dielectric layer is etched to form a window exposing a portion of the switch body, where the first dielectric layer is etched so as to slope away smoothly from the boundary of the window. A contact is subsequently on the first surface of the switch in the window of the first dielectric layer.

A further set of aspect relate to a method of forming a high voltage electrical switch, including receiving a semi-conductor switch body and forming a first metal contact upon a first surface of the switch body. Forming the first metal contact is performed at a temperature so that a portion of the switch body near the first metal contact reacts with it. The first metal contact and the reacted portion of the switch body are subsequently etched away thereby forming a well in the first surface of the switch body, the edges of the well being rounded off A second metal contact is then formed in the well.

Additional aspects relate to a method of forming a high voltage electrical switch and include receiving a semi-conductor switch body and forming a first metal contact upon a first surface of the switch body. An area of the first surface of the switch body adjacent to the contact is treated to make the area adjacent to the contact highly resistive.

In another set of aspects relating to a method of forming a high voltage electrical switch, a semi-conductor switch body is received and a first metal contact is formed upon a first surface of the switch body. A second metal contact id formed upon a second surface of the switch, where the first and second surfaces are opposing surfaces of the switch body, where the first and second metal contacts are formed to have differing geometries upon the first and second surfaces.

Still further aspect relate to forming a high voltage electrical switch include receiving a semi-conductor switch body and subsequently treating the switch body to generate charge traps within the switch body. First and second metal contacts are formed on opposing surfaces of the switch body.

Aspect also related to a method of forming an optically activated high voltage electrical switch. This includes receiving a switch body for an optically activated switch and forming first and second contacts on opposing surfaces of the switch body, where the first contact is formed to have to have one or more apertures therein through which the switch body can be illuminated.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIG. 1 is a schematic representation of opto-electric switch and the electric field levels generated near the top contact.

FIG. 2 illustrates a cast dielectric on the switch body.

FIGS. 3a-3d illustrate the deposition and etch of a dielectric on a switch body, followed by the formation of a contact.

FIGS. 4a-4g illustrate a process of forming and etching alternating dielectric and conductive layers on a switch body.

FIG. 5 is a schematic representation of how the process of forming the contact affects the underlying switch body.

FIG. 6 shows a well formed through a process of forming and removing contacts on the switch body.

FIG. 7 illustrates a switch with a non-conductive region formed to the sides of the contact.

FIG. 8 is a schematic representation of a switch with asymmetric contacts.

FIG. 9 is a schematic representation of a switch structure that allows for illumination from the top surface.]

FIG. 10 illustrates a process flow for generating more traps after the switch body is grown.

### DETAILED DESCRIPTION

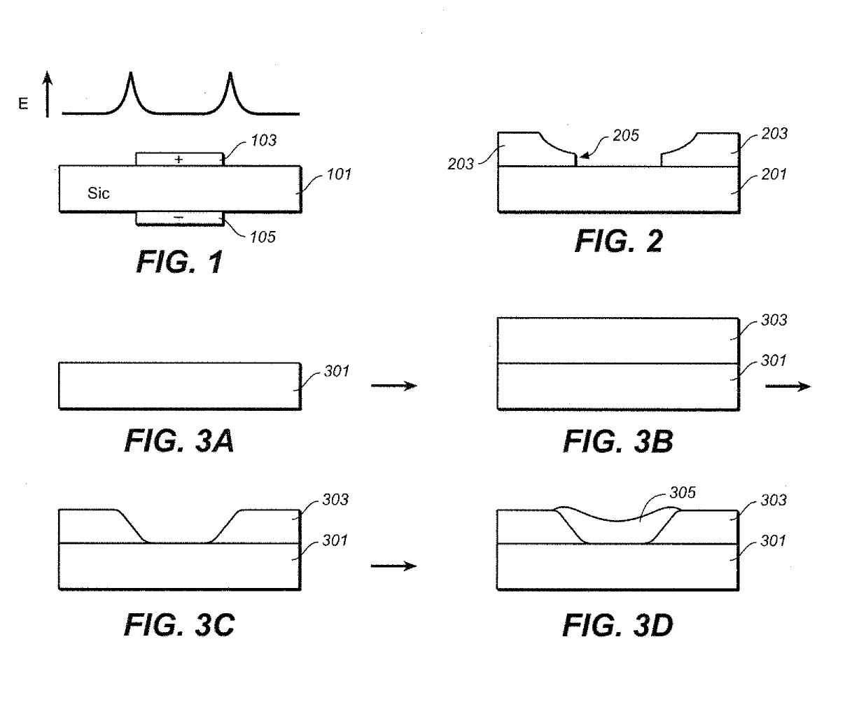

FIG. 1 is a schematic representation of the sort of opto-switch described in the Background, where, in this example, the body 101 is formed of silicon carbide with top 103 and bottom 105 contacts formed on the switch body. A positive voltage can then be applied at the top contact, while the bottom contact is at ground or some other lower level. (The switch could of course be arranged in any orientation, but for here the contact used for the positive and ground or negative voltage levels will here be taken as the top and bottom, respectively.) The switch body is then illuminated from a light source, such as a laser, to trigger the switch. Example of uses for such a switch are described in more detail in US patent publication 2012-0146553, where it is incorporated into a blumlein structure, and in U.S. patent application Ser. No. 13/352,187, where is used in a high voltage RF opto-electric multiplier. More detail on the switch itself can be found in the references cited in the Background.

The following will consider various aspects of such switches: the contacts, the switch body, and illumination. They are each considered under the corresponding heading below.

### Contacts

Returning to FIG. 1, the contacts 103 and 105 are placed on the top and bottom of the switch body 101. In a typical application, a high voltage across the two contacts is applied. This results in high field levels at the edges of the contacts, as shown at the top of figure. One way to reduce these high field levels at the edges of the contacts is to introduce curved edges for the contacts; however, forming the contact by itself to have this sort of contour is usually difficult. One way to achieve this is, as shown in FIG. 2, would be to cast a dielectric 203 (such as polymer or epoxy) on top of SiC body 201 with a bowl shaped depression, into which the contact could be formed. However, this is difficult to achieve without a step (at arrow 205), which again results in a fairly large field spike. Also, tastable dielectrics typically cannot handle the high temperature (˜1000 C) involved in the subsequent forming of the metal contacts.

A process that provide a smooth edge is illustrated with respect to FIGS. 3a-3d: taking the SiC switch body 301 at FIG. 3a, a dielectric 303, such as a silicon nitride or silicon oxide, is deposited (FIG. 3b), then a photoresist mask, and which is then etched to provide what is shown in FIG. 3c. Usually, when forming circuits, the desired result of the etch is to have the elements have vertical edges, so anisotropic etches and other techniques are used to get this. In this case, however, the desired result that is actually wanted is the sort of sloped edge as shown in FIG. 3c. By having this slope, the process can then form contact 305 over the window without the sharp edges, as shown in FIG. 3d. The dielectrics available for this sort of process can generally handle the sort of temperatures typically involved in forming the contacts. Also, as these dielectrics will typically have a dielectric constant several times higher than that of the underlying SiC switch body, this can allow the structure to handle higher gradients, effectively strengthening the SIC switch body.

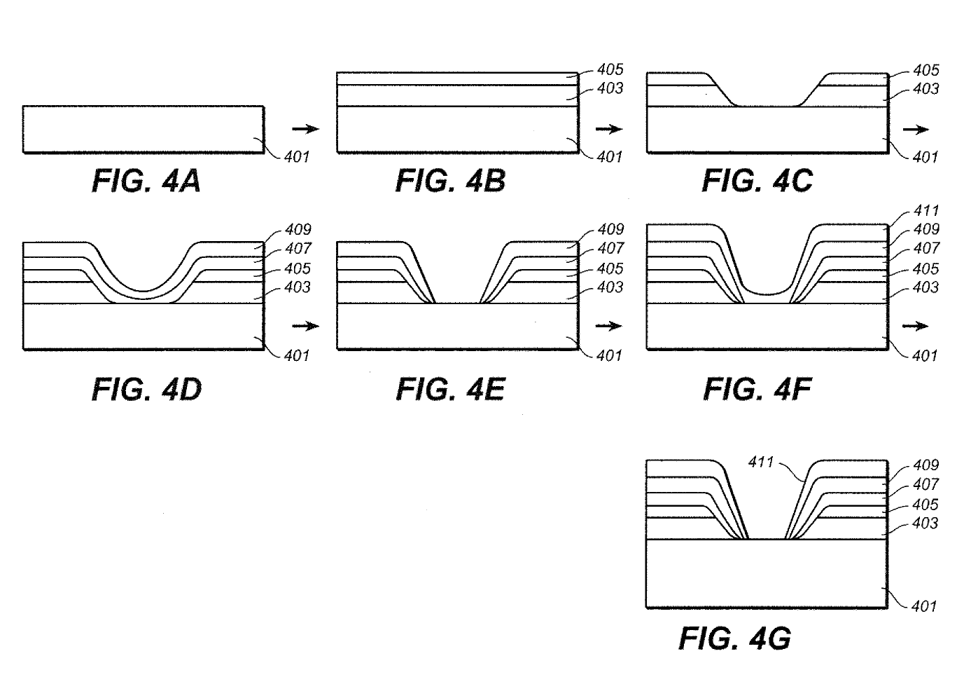

The dielectric layer, such as 303, can have defects. If there is a hole under the contact 305, this can lead to punch through. One way to deal with this is to lay down an alternating series of dielectric and metal layers (one or more metal layers with dielectric above and below each), and then etch. This way, if there is defect in the dielectric, the metal barrier will stop a punch through. The contact will eventually be formed on this structure, but should not contact these inter-dielectric metal layers. This can be dealt with by how the etch, or etches, are done. An example is shown in FIGS. 4a-g.

Here a first dielectric layer 403 is deposited on the switch body 401, followed by a metal layer 405, after which an etch is performed leading to the structure of FIG. 4c. This is then repeated at FIGS. 4d and 4e for layers 407 and 409, after which a final dielectric layer 411 is put down. This last dielectric layer then has its central portion etched away (FIG. 4g), leaving the edges of the metal layers covered, but leaving the window to the switch body exposed. Different number of layers and different numbers of etchings at differ stages can be used, but the final metal layer should be etched before the last dielectric is put down (and then etched) so that the edges of metal layers are not exposed. In any case, once the last etch is done (FIG. 4g) the metal layer can be formed.

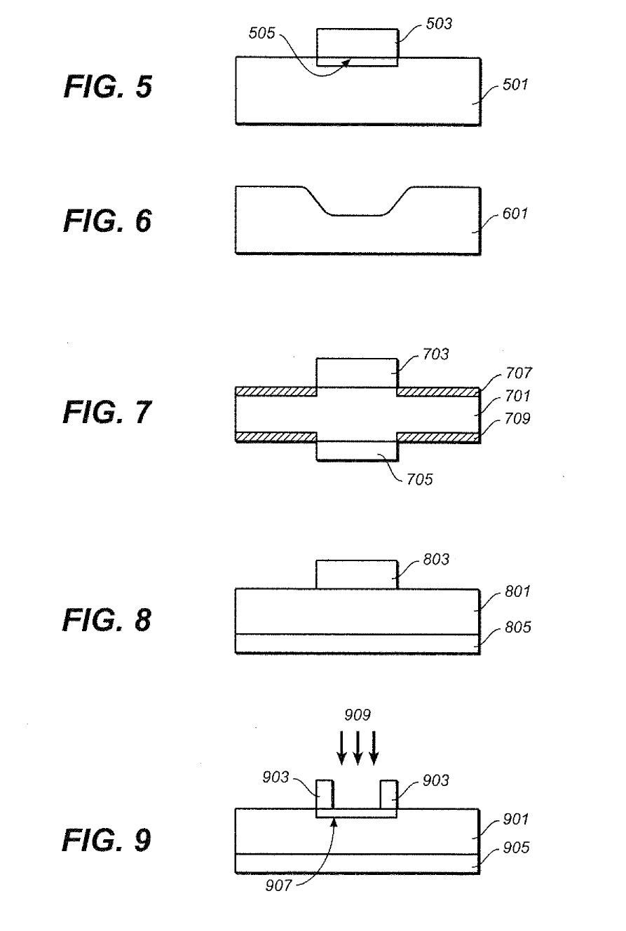

An alternate approach to reducing the sharpness of the contacts edge is to form a depression or well in the body of the switch structure, rather than placing a layer on top of the switch body. In the process of forming the contact, the metal 503 is laid down on the switch body 501 and, at the temperatures involved in forming the contact, the SIC of a layer 505 near the metal will react. This is shown in FIG. 5. In a typical process, this reacted layer could be on the order of 50-100 nm, which is on the same order as the formed contact thickness. The depth will also depend on the metal used for the contact: for instance, as nickel can form NiSi₂ it can form a reacted layer of about twice the depth of a metal that reacts with a single silicon atom per metal atom. The contact, along with the reacted portion of the switch body can then be etched away, leaving a well into which a new contact can then be formed and where, in the resultant alloying process, the edges of the well will be rounded off. This process can be taken through multiple iterations, successively deepening and smoothing the edges of the well. This is shown in FIG. 6, prior to the final contact layer being added. Relative to the embodiments described above where a dielectric layer is formed on the surface, this arrangement does not result in a layer with the differing dielectric constant on the SiC body 601.

Another approach to reducing the peaking at the edges of the contact is to limit the conductivity at the edge of the contact by making the area to the sides of the contact very resistive. For example, argon can be implanted on the surface of the switch body to the sides of the contact. This is shown in FIG. 7, where argon has been implanted at 707 and 709 into both the top and bottom surfaces to the sides of the contacts 703 and 704 and can be done mainly in the areas adjacent to the edges of the contact.

Any of the preceding embodiments related to the reducing the field peaking at the contact edges can be applied to either or both contacts, although aside from the argon implantation, this has only been shown for top conductor. It is often sufficient to just perform these processes at the top surface, which is placed at the high positive voltage, and not to the bottom contact. Another, complementary approach is to use a different geometry for the top and bottom contacts. An asymmetric arrangement can keep the field peaking on the top from aligning with the peaking on the lower side, reducing the stress between these points. An example of this is shown in FIG. 8, where the lower contact 805 covers the whole bottom surface of the switch body, while the top contact 803 is as before. As with the other embodiments described above, these approaches for treating the contacts are complimentary in that they can be used on their own or variously combined.

### Switch Body

Considering now the photo-switch body itself, in applications such as the blumlein structures described in US patent publication 2012-0146553 quite high voltages are applied across a relatively thin switch body. The switch body needs sufficient traps to support the injected charge at the desired voltage without hitting the trap filling voltage. Once the trap filling voltage is reached, the amount of current through the switch increases significantly, leading to heating and switch damage. Consequently, the device performance can be improved by adding traps or defects to the switch body. In growing the SiC switch body, the amount of traps that can be generated is limited as the material can only be doped so much. To further increase the number of traps, techniques are applied to generate more traps after the body is grown, such as irradiating the body.

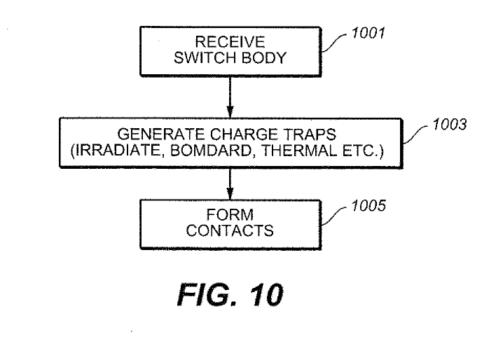

Another trap generation method is thermal shock: the switch body is heated and then rapidly cooled, reducing the crystallinity of the SiC. The material can be taken though multiple cycles to increase this effect. Alternately, or additionally, the structure can also be subjected to particle bombardment (such as neutrons or electrons), where the collisions will increase the amount of disorder with the crystal structure. FIG. 10 is a flow to illustrate the process schematically. At 1001 a switch body is received and then treated (1003) by one or more of these methods to generate traps. The contacts are then typically formed after (1005), which can be done according to the various techniques described above.

Any of these techniques can be applied to switch body allowing for higher voltages to be placed across the device in application such a blumlein structure in, for example, a particle accelerator application.

### Illumination

The exemplary embodiments described here are optical-electric switches, where the switch is activated by being illuminated by a light source. As the contacts are formed on the top and bottom surfaces of the switch, such opto-switches are typically illuminated from the side. Also, the placement of the switch within a device often restricts the access to the top and bottom of the switch by an illumination source. An example of this is again where the switch is placed within a blumlein and then several such blumlein stages are stacked into a compact particle accelerator, such as described in US patent publication 2012-0146553, where if the stages directly stacked over each other only the sides of the switches are readily accessible. The optical properties of switch body can be tuned to improve switch operation, by altering the absorptivity or tuning the switch's thickness. Although this can help the switch's properties when illuminated from the side, it can still be more effective to illuminate the switch in the thinner vertical direction.

To effectively illuminate the switch from the top or bottom, however, it may be preferable to alter the contact structure. An example of this is shown in FIG. 9. Here the top contact 903 has an opening through the switch and can be illuminated, as shown at 909. Although shown here as two separate parts, a number of different arrangements can be used, where two or more distinct parts form the top contact, or the shown two pieces may be connected; for example, this could form part of an annular contact, but which appears separate in this cross-section. The illumination is here incident upon an implanted under-layer 907. The bottom contact 905 of this example is as described with respect to FIG. 8.

The under-layer in 907 in FIG. 9 is a transparent conductive layer introduced to change the absorptive properties and have more uniform absorption where the light is incident on the switch. An n-type material is good for this purpose to reduce spreading into the switch body. It can also be preferable for an optical matching layer to be formed on the top, as it can be done on the wafer when the SiC body is formed, whereas the formation of such a layer on the side would require a separate step in the manufacturing process that cannot be integrated into a large scale wafer process.

As noted, a number of different contact shapes can be used. In addition to several separate pieces or an annular sort of contact, it could be in the form of a grid having multiple apertures to allow the illumination to reach the under-layer. As also noted above, the space available in order to provide this illumination thorough the top contact may be limited. For example, in the stacked blumlein accelerator example, some access to the top of the switches may be provided by differentially offsetting the switches relative to the structure, but access may still be fairly restricted, so that illumination could be provided by use of a crystal, for example, to provide incident illumination at a usable angle.

### CONCLUSION

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated.

It is claimed:

1. A method of forming a high voltage electrical switch, comprising:
receiving a semi-conductor switch body;
forming a first dielectric layer over a first surface of the switch body;
etching the first dielectric layer to form a window exposing a portion of the switch body, where the first dielectric layer is etched so as to slope away smoothly from the boundary of the window; and
subsequently forming a contact on the first surface of the switch in the window of the first dielectric layer.

2. The method of claim 1, further comprising:
prior to forming the first dielectric layer:
forming second dielectric layer on the first surface of the switch body;
forming a first metal layer over the second dielectric layer; and
subsequently performing an etch to expose a portion of the switch body,
wherein the first dielectric layer is subsequently formed over the resultant structure and,
wherein when the first dielectric layer is etched so that first metal layer adjacent to the window region remains covered by the first dielectric layer.

3. The method of claim 2, further comprising:
subsequent to forming the first metal layer and prior to performing the etch to expose a portion of the switch body:
alternately forming one or more additional dielectric and metal layers,
wherein when the first dielectric layer is etched so that all of the metal layers adjacent to the window region remains covered by the first dielectric layer.

4. The method of claim 1, wherein the switch body is formed of silicon carbide.

5. A method of forming a high voltage electrical switch, comprising:
receiving a semi-conductor switch body;
forming a first metal contact upon a first surface of the switch body, wherein forming the first metal contact is performed at a temperature so that a portion of the switch body near the first metal contact reacts therewith;
subsequently etching away the first metal contact and the reacted portion of the switch body, thereby forming a well in the first surface of the switch body, the edges of the well being rounded off; and
forming a second metal contact in the well.

6. The method of claim 5, wherein the reacted portion is in a range of 50 nm to 100 nm thick.

7. The method of claim 5, wherein the metal contact includes NiSi₂.

8. The method of claim 5, wherein forming the second metal contact is performed at a temperature so that a portion of the switch body near the second metal contact reacts therewith, the method further comprising:
subsequently etching away the second metal contact and the reacted portion of the switch body, thereby deepening the well in the first surface of the switch body, the edges of the well being rounded off; and
forming a third metal contact in the well.

9. A method of forming a high voltage electrical switch, comprising:
receiving a semi-conductor switch body;
forming a first metal contact upon a first surface of the switch body, and
treating an area of the first surface of the switch body adjacent to the contact to make the area adjacent to the contact highly resistive.

10. The method of claim 9, wherein said treating the area of the first surface includes:
performing an implanting operation on the surface of the switch body.

11. The method of claim 10, wherein the implanting operation is concentrated on the area of the switch body adjacent the contact.

12. The method of claim 10, wherein the implanting operation includes the implanting of argon.

14. A method of forming a high voltage electrical switch, comprising:
receiving a semi-conductor switch body;
forming a first metal contact upon a first surface of the switch body; and
forming a second metal contact upon a second surface of the switch, where the first and second surfaces are opposing surfaces of the switch body, and
wherein the first and second metal contacts are formed to have differing geometries upon the first and second surfaces.

15. The method of claim 14, wherein the second switch is formed to cover the whole of the second surface and the first switch is formed to cover only a portion of the first surface.

16. A method of forming a high voltage electrical switch, comprising:
receiving a semi-conductor switch body;
subsequently treating the switch body to generate charge traps within the switch body; and
forming first and second metal contacts on opposing surfaces of the switch body.

17. The method of claim 16, wherein treating the switch body includes irradiating the switch body.

18. The method of claim 16, wherein treating the switch body includes subjecting the switch body to particle bombardment.

19. The method of claim 18, wherein treating the particle bombardment includes neutron bombardment.

20. The method of claim 18, wherein treating the particle bombardment includes electron bombardment.

21. The method of claim 16, wherein treating the switch body includes subjecting the switch body to one or more cycles of thermal shock, wherein the switch body is heated and then rapidly cooled.

22. A method of forming an optically activated high voltage electrical switch, comprising:
receiving a switch body for an optically activated switch;
forming first and second contacts on opposing surfaces of the switch body, wherein the first contact is formed to have to have one or more apertures therein through which the switch body can be illuminated.

23. The method of claim 22, wherein the first contact formed of a plurality of distinct parts.

24. The method of claim 22, wherein the first contact is annular.

25. The method of claim 22, wherein the first contact is annular.

26. The method of claim 22, wherein the first contact is of a grid-type pattern with multiple apertures.

27. The method of claim 22, further comprising:
forming a layer in the region over where the one or more apertures will be located to improve the optical absorptive properties of the region.

28. The method of claim 27, where said layer is a transparent conductive layer.

29. The method of claim 27, where said layer is of an n-type material.
